(19) United States
(12) Patent Application Publication
(10) Pub. No.: US 2017/0135227 A1
(43) Pub. Date: May 11, 2017

(54) Engineered Residue Solder Paste Technology

(71) Applicant: Alpha Metals, Inc., South Plainfield, NJ (US)

(72) Inventors: Hosur Venkatagiriyappa Ramakrishna, South Plainfield, NJ (US); Morgana De Avila Ribas, South Plainfield, NJ (US); Ranjit Pandher, South Plainfield, NJ (US); Siuli Sarkar, South Plainfield, NJ (US); Sutapa Mukherjee, South Plainfield, NJ (US); Bawa Singh, South Plainfield, NJ (US)

(21) Appl. No.: 15/318,829

(22) PCT Filed: Jun. 19, 2015
(86) PCT No.: PCT/GB2015/051797

§ 371 Date: Dec. 14, 2016

(30) Foreign Application Priority Data
Jun. 19, 2014 (IN) 2984/CHE/2014

(51) Int. Cl. H05K 3/34; H05K 1/09; H05K 1/11; B23K 35/362; B23K 1/00; B23K 35/02; B23K 35/36; H01L 23/00; H05K 1/18

(52) U.S. Cl. CPC H05K 3/3489; H05K 3/3431; H01L 24/83; H05K 1/09; H05K 1/111; H05K 1/181; B23K 1/0016; B23K 35/025; B23K 35/3613; B23K 35/362; H01L 2224/32225; H01L 2224/83815; H01L 2224/2929; H01L 2924/0665; H01L 2224/83024; H01L 2224/29388; H01L 2224/29393; H01L 2224/2939

(57) ABSTRACT

A method of forming a solder joint, the method comprising: (i) providing a solder flux; (ii) providing solder particles; (iii) providing two or more work pieces to be joined; and (iv) heating the solder flux and the solder particles in the vicinity of the two or more work pieces to be joined to form: (i) a solder joint between the two or more work pieces to be joined, and (ii) a solder flux residue. The solder flux residue substantially covers the exposed surfaces of the solder joint.

### FIELD OF THE INVENTION

The invention relates to a method of forming a solder joint. In particular, the invention relates to a method of forming a solder joint exhibiting improved mechanical and/or thermo-mechanical properties.

### BACKGROUND OF THE INVENTION

Soldering in electronics has various functions such as, for example, providing an electrical contact, physically joining two or more parts, and providing a heat dissipation path. As the size of the electronic components is continuously shrinking, so does the size of the solder interconnects. The smaller size of the interconnections usually means a relatively weaker mechanical strength of the joint.

Another trend in the electronic industry is ever increasing popularity of portable electronics such as, for example, cell phones, laptops, tablets, e-readers, audio/video players, wearables. These portable devices put additional, more stringent requirements on the electrical and mechanical reliability of the electronic components and packages used there in. For example, when such a device is accidently dropped all the parts inside have to withstand the huge mechanical stresses to which they are subjected. Many times designers of these devices face a situation where mechanical strength provided by small size solder interconnections is not good enough to withstand such mechanical shocks.

Another trend in electronics industry is ever increasing use of electronics in automotive applications. Electronic devices and control circuits are being used in practically every section of a modern car. Electronic devices/packages/modules used in automobiles face high shock, vibration and temperatures during operation. In such situations small solder interconnections made in the traditional way may not meet thermo-mechanical reliability demands. Therefore there is need to increase the mechanical strength of the electrical, mechanical and thermal interconnection made using solders.

In general the solder-pad interface is perhaps the weakest link in electronic interconnects. There is need to strengthen this weakest link to improve mechanical and thermal reliability of the electronic assembly. Most important is to strengthen and maintain the mechanical properties of the interconnections, including the bulk of the material and the solder-pad interfaces before and after thermal cycling. Materials present in the board-component assembly may have differing coefficients of thermal expansion (CTE), and the materials may contract and expand during thermal cycling. As a result, during thermal cycling, the solder joint is subjected to cyclic contractions and expansions that ultimately can deteriorate and weaken the solder joints. The solder-pad interface with the largest CTE mismatch is often the weakest link.

### SUMMARY OF THE INVENTION

The present invention seeks to tackle at least some of the problems associated with the prior art or at least to provide a commercially acceptable alternative solution thereto.

The present invention provides a method of forming a solder joint, the method comprising:
providing a solder flux;
providing solder particles;
providing two or more work pieces to be joined; and
heating the solder flux and the solder particles in the vicinity of the two or more work pieces to be joined to form: (i) a solder joint between the two or more work pieces to be joined, and (ii) a solder flux residue,

wherein the solder flux residue substantially covers the exposed surfaces of the solder joint.

The method results in a solder joint exhibiting more favourable mechanical properties, for example increased strength, increased reliability and increased resistance to thermal cycling.

Each aspect or embodiment as defined herein may be combined with any other aspect(s) or embodiments) unless clearly indicated to the contrary. In particular, any features indicated as being preferred or advantageous may be combined with any other feature indicated as being preferred or advantageous.

### BRIEF DESCRIPTION OF THE DRAWINGS

The invention will now be described in relation to the following non-limiting drawings in which:

FIG. 1 shows a flow chart of the method of the present invention.

FIG. 2 shows a schematic of a solder joint formed using a conventional method (top) and a schematic of a solder joint formed using the method of the present invention (bottom).

FIG. 3 shows hypothetical stress-strain curves of three materials.

FIG. 4 shows Coefficients of Thermal Expansion (CTE) of a typical solder and three types of other joint reinforcing materials.

FIG. 5 shows results of impact bend testing.

FIG. 6 shows results of drop shock testing.

FIG. 7 shows results of thermal cycling testing.

### DETAILED DESCRIPTION OF THE PREFERRED EMBODIMENTS

The term “solder flux” as used herein encompasses a species used to prevent oxidation during a soldering process. The solder flux may also provide some form of chemical cleaning prior to soldering.

The term “solder residue” as used herein encompasses the residue formed as a result of heating of a solder flux during a soldering process. Without being bound by theory, it is considered that the solder flux residue forms when at least some of the solvent is evaporated from the solder flux.

The solder flux and solder particles may be provided separately. For example, the solder flux may be applied separately in liquid, paste or film form, whereas the solder particles may be provided in the form of a powder, sheet, stick or wire. Alternatively, the solder flux and solder particles may be provided together, for example in the form of a solder paste.

The two or more work pieces to be joined (i.e. to be joined by the resulting solder joint) may comprise, for example, an electronic component (e.g. a chip resistor or a chip capacitor) and a copper pad of a printed circuit board.

The temperature at which the solder flux and solder particles are heated will depend on the specific solder flux and solder particles being employed. However, typical heating temperatures are from 140 to 280° C. For example, when so-called “low temperature” solder particles are used, the heating temperature will typically be from 140 to 200° C., when so-called “medium temperature” solder particles are used, the heating temperature will typically be from 200 to 240° C., and when so-called “high temperature” solder particles are used, the heating temperature will typically be from 240 to 280° C.

The solder flux and solder particles are heated in the vicinity of the two or more work pieces to be joined. For example, when the solder joint is to be formed between the work pieces, the solder flux and solder particles are typically placed between the work pieces and in contact with the two work pieces and then heated. Alternatively, when the solder joint is to be formed against the join between two or more work pieces (e.g. when the work pieces are to be joined end-to-end), the solder flux and solder particles may be placed on the join between the work pieces before being heated.

The solder flux (or alternatively the solder paste when the solder flux and solder particles are provided together in a solder paste) may be applied to the two or more work pieces by, for example, printing, dispensing, jetting, dipping and/or pin transfer. Such techniques are known in the art. The flux may be applied in the form of a liquid, paste or film. The flux may be applied as a pre-applied paste flux for preforms, as a paste flux in solder film form and/or as a paste flux in film form.

The flux residue substantially covers the exposed surfaces of the solder joint. Typically the flux residue covers at least 90% of the exposed surface, more typically at least 95% of the exposed surface, even more typically the entire exposed surface.

The exposed surfaces of the solder joint refers to the outer surfaces of the solder joint that are not in contact with the two or more work pieces. For example, when the solder joint is sandwiched between two work pieces, the exposed surfaces of the solder joint will be the surfaces that are substantially perpendicular to the layers of the sandwich. Alternatively, when the solder joint is formed at the side of the join between two work pieces, the exposed surface will be the surfaces of the solder joint that are opposite the join.

The exposed surfaces may comprise a single surface or multiple surfaces.

The inventors have surprisingly found that the method of the present invention may result in a solder joint that exhibits improved mechanical properties in comparison to conventional solder joint forming methods. For example, the resulting solder joint may exhibit one or more of improved drop shock resistance, improved thermal cycling performance, improved thermal shock resistance, increased shear strength, increased flexural strength and other thermal-mechanical characteristics. As a result, the reliability of the solder joint is improved.

This is particularly advantageous when the solder joints are required to be small in size. Accordingly, the method is particularly useful when used to form solder joints in a portable electronic device such as, for example, a cell phone, a laptop computer, a tablet computer, an e-reader, an audio/video player, or a watch. Such devices require small solder joints that are capable of withstanding significant stresses, for example as a result of being dropped. Such reliable solder joints are also advantageous in the automotive industry, where solder joints are typically exposed to high shock, high temperatures and high vibration.

The inventors have discovered that in a conventional solder joint forming method, flux material in a solder paste typically spreads and moves away from the solder joint. In the method of the present invention, without being bound by theory it is considered that by ensuring that the solder flux residue substantially covers the exposed surfaces of the solder joint, the solder joint may be reinforced, for example by redistributing stresses away from the joint. In addition, problems associated with solder flux spread can be reduced, for example less flux available for soldering and reliability concerns such as, for example, discolouration of the pad, electromigration failures and discolouration of the residue itself.

The solder flux preferably comprises:
an organic solvent;
an epoxy resin;
a hardener; and
a catalyst.

On heating the flux, the epoxy resin may undergo cross-linking, meaning that the solder flux residue may comprise cross-linked epoxy resin. This may serve to improve the mechanical properties of the formed solid joint. The epoxy resin may provide the solder flux residue with increased ductility. Advantageously, this may serve to provide additional strength to the solder joint, and may enable it to withstand higher stresses.

The organic solvent is typically a high boiling point organic solvent, preferably having a boiling point of at least 280° C. Suitable organic solvents having a boiling point of at least 280° C. for use in the present invention include, for example, butyl carbitol, diethylene glycol mono hexyl ether, and glycol ethers. The epoxy resin may be a multi-funtional type epoxy resin and/or an epoxy resin with high molecular weight. The hardener may comprise a phenolic group containing hardening agent and/or may be an anhydride-based hardener, typically a liquid anhydride-based hardener. The catalyst may comprise a substituted aromatic amine catalyst, and/or a phosphene-based salt catalyst and/or an amide-based catalyst.

The solder flux preferably further comprises:
an activator; and/or
a bonding agent; and/or
a stress modifier; and/or
a degassing agent.

The activator may comprise, for example a carboxylic acid. The stress modifier may comprise, for example, a liquid type stress modifier.

The solder flux preferably comprises, based on the total weight of the solder flux:
from 20 to 40 wt. % organic solvent; and/or
from 5 to 45 wt. % epoxy resin; and/or
from 2 to 36 wt. % hardener; and/or
from 0.1 to 15 wt. % catalyst; and/or
from 10 to 20 wt. % activator; and/or
from 0.1 to 2 wt. % bonding agent; and/or
from 0.1 to 4 wt. % stress modifier; and/or
from 0.1 to 2 wt. % degassing agent.

The presence of such species in the recited ranges may provide the flux with favourable viscosity, tackiness and/or fluidity during heating (e.g. reflow). Such characteristics may serve to ensure that a high proportion of the flux remains around the site of the solder joint during reflow. This may serve to ensure that more flux is available for soldering. In addition, this may help to ensure that the solder flux residue formed during heating substantially covers the exposed surfaces of the solder joint. Furthermore, unfavourable situations caused by solder flux spread may be reduced such as, for example, discoloration of pads, electromigration failures and discolouration of the solder residue.

The solder flux preferably further comprises a filler. The inclusion of a filler may allow control of the mechanical and/or thermo-mechanical properties of the solder flux and/or the solder flux residue. In particular, the presence of a filler may serve to decrease CTE mismatch between the solder flux residue and the solder joint, thereby increasing the resistance to thermal cycling fatigue.

The solder flux preferably comprises from 0.1 to 40 wt. % filler, more preferably from 0.1 to 10 wt. % filler, even more preferably from 0.1 to 5 wt. % filler based on the total weight of the solder flux. The solder flux may comprise at least 0.01 wt. % filler, or at least 0.1 wt. filler, or at least 0.5 wt. % filler, or at least 1 wt. % filler, or at least 2 wt. % filler, or at least 5 wt. % filler. The solder flux may comprise up to 40 wt. % filler, or up to 25 wt. % filler, or up to 15 wt. % filler, or up to 10 wt. % filler, or up to 5 wt. % filler or up to 2 wt. % filler. The presence of filler in the recited ranges may serve to improve the mechanical and/or thermo-mechanical properties of the solder flux and/or solder flux residue. Higher levels of filler may serve result in the solder flux exhibiting an unfavourably high viscosity. Lower levels may result in only minimal reduction in the mismatch of CTE.

The filler may comprises a high aspect ratio filler (e.g. a filler having an aspect ratio of greater than 1, typically greater than 2, more typically greater than 5), the high aspect ratio filler comprising one or more of glass fibers, mica, nanoclays, graphene, functionalized graphene, diamond, carbon nano tubes, graphite and carbon fibers, boron nitride, synthetic and natural fibers. Such fillers may serve to improve the mechanical and/or thermo-mechanical properties of the solder flux and/or solder flux residue. In particular, the presence of a high aspect ratio filler may serve to decrease CTE mismatch without increasing the viscosity of the solder flux to an unfavourable level.

The filler may comprise a low aspect ratio filler (e.g. a filler having an aspect ratio of less than 2, typically less than 1.5, more typically around 1), the low aspect ratio filler comprising one or more of: silica, aluminum oxide, zinc oxide, aluminum nitride, dioxide, polyhedral oligomeric silsesquioxanes, metal-coated particles, talc, kaolin, wallastonite and glass spheres.

The filler may comprise an antiblock, lubricating filler comprising one or more of silica, calcium carbonate, PTFE and graphite-related fillers. Such fillers may serve to provide more favourable surface properties to the solder flux and/or solder flux residue.

The filler may comprise fillers to reduce isotropic shrinkage and/or reduced warpage, for example particulate fillers, glass beads and/or mica. Such fillers may serve to improve the dimensional stability of the solder flux and/or solder flux residue.

The filler may comprise one or more of: fillers to modify electrical and/or magnetic properties (e.g. conductive, non-conductive and ferromagnetic metal fillers, carbon related fillers and fibers and mica); filler for radiation absorption (e.g. metal particle fillers, lead oxide and leaded glass), fillers to modify optical properties (e.g. nucleators, clarifiers, pigments, fine particulates and mica/pigment hybrids) and fillers to control damping (e.g. flake fillers, glass and barium sulphate).

The epoxy resin preferably comprises a rubber (typically a liquid rubber) dispersed therein. Epoxy resins in the solder flux residue may be brittle. The rubber may form a dispersed phase bonded with the epoxy resin and prevents crack propagation within the cured epoxy resin matrix (solder flux residue). The dispersed rubber phase may act as a dissipation centre of mechanical energy by cavitations and shear yielding inducing the increase of crack growth resistance and excellent fracture properties. The presence of the rubber may increase the ductility of the solder flux residue, thereby increasing the mechanical properties of the solder joint. In particular, the presence of a ductile solder flux residue may serve to provide improved drop shock resistance.

In conventional solder joints, reliability of the solder joint may be reduced due to differences in the coefficient of thermal expansion (CTE) of the work pieces and the solder joint. The presence of the rubber in the solder flux residue may serve to negate the effects of the differences in CTE between the work pieces and the solder joint, thereby increasing the resistance to thermal cycling fatigue.

Differences in the CTE of the material of the solder joint and the solder flux residue may also result in reduced thermal cycling resistance. Accordingly, the solder flux residue preferably has a CTE close to that of the material of the solder joint. Preferably, the CTEs of the solder joint material and the solder flux differ by less than 150%, more preferably less than 100%, even more preferably less than 60%, still even more preferably less than 50%. Such CTE matches may be achieved, for example, by use of the rubber disclosed above.

The epoxy resin preferably comprises up to 10 wt. % liquid rubber based on the total weight of the solder flux, more preferably from 0.1 to 10 wt. % liquid rubber. The epoxy resin may comprise at least 0.1 wt. % rubber, or at least 1 wt. % rubber or at least 2 wt. % rubber based on the total weight of the solder flux. The epoxy resin may comprise 10 wt. % or less rubber, or 8 wt. % or less rubber, or 5 wt. % or less rubber based on the total weight of the solder flux. This may provide the solder flux residue with particularly favourable ductility and may provide the solder joint with particularly favourable mechanical and/or thermo-mechanical properties.

The liquid rubber preferably comprises an acrylonitrile butadiene type rubber having one or more terminal groups comprising carboxyl, hydroxyl and/or amine groups. Such a rubber is essentially an acrylonitrile and butadiene copolymer obtained by an emulsion polymerization method. Such a rubber may provide the solder flux with particularly favourable ductility and may result in the solder flux residue and solder joint exhibiting particularly favourable mechanical and thermo-mechanical properties.

The solder particles are preferably lead-free solder particles. Suitable lead-free solder particles may comprise, for example, Sn, Sn-containing alloys, Sn—Bi alloys, Sn—Cu alloys, Sn—Ag alloys, SAC-type alloys and combinations of two or more thereof. Other suitable lead-free solders will be known to the skilled person.

In one embodiment, the two or more work pieces to be joined comprise an electronic component and a copper pad of a printed circuit board. It is desirable that solder joints between such work pieces exhibit favourable mechanical and/or thermo-mechanical properties and exhibit high reliability.

The solder joint may be formed during a manufacturing method selected from: a surface mount technology (SMT) method, a die and component attach method, a package on package (POP) method, a chip scale package (CSP) method, a ball grid array (BGA) method, a flip chip method, a can shield attachment method and a camera lens attachment method.

In a further aspect, the present invention provides a solder joint obtainable by the method described herein.

In a further aspect, the present invention provides a solder flux for use in the method described herein, the solder flux comprising:
an organic solvent;
an epoxy resin;
a hardener; and
a catalyst,

and optionally one or more of:
an activator;
a bonding agent;
a stress modifier;
a degassing agent; and
a filler.

The preferable and optional features and advantages of the first aspect of the present invention apply equally to this aspect of the present invention.

The epoxy resin preferably comprises a liquid rubber dispersed therein. The epoxy resin preferably comprises from 0.1 to 10 wt. % liquid rubber based on the total weight of the solder flux. The liquid rubber preferably comprises an acrylonitrile butadiene type rubber having one or more terminal groups comprising carboxyl, hydroxyl and amine groups.

The solder flux is typically printable, and/or jettable, and/or dippable and/or pin-transferable.

In a preferred embodiment, the solder flux comprises:
20 to 40% by weight organic high-boiling solvents;
5 to 45% by weight epoxy resins;
2 to 36% by weight hardeners;
10 to 20% by weight carboxylic acid as an activator;
0.1 to 15% by weight catalysts;
0.1 to 2% by weight bonding agent;
0.1 to 4% by weight liquid type stress modifier; and
0.1 to 2% by weight degassing agent.

In another preferred embodiment, the solder flux comprises:
20 to 40% by weight organic high-boiling solvents;
5 to 45% by weight epoxy resins;
2 to 36% by weight hardeners;
10 to 20% by weight carboxylic acid as an activator;
0.1 to 15% by weight catalysts;
0.1 to 2% by weight bonding agent;
0.1 to 4% by weight liquid type stress modifier;
0.1 to 2% by weight degassing agent; and
0.1 to 10% by weight glass fiber as filler.

In another preferred embodiment, the solder flux comprises:
20 to 40% by weight organic high-boiling solvents;
5 to 45% by weight epoxy resins;
2 to 36% by weight hardeners;
10 to 20% by weight carboxylic acid as an activator;
0.1 to 15% by weight catalysts;
0.1 to 2% by weight bonding agent;
0.1 to 4% by weight liquid type stress modifier;
0.1 to 2% by weight degassing agent; and
0.1 to 5% by weight graphene as filler.

In another preferred embodiment, the solder flux comprises:
20 to 40% by weight organic high-boiling solvents;
5 to 45% by weight epoxy resins;
2 to 36% by weight hardeners;
10 to 20% by weight carboxylic acid as an activator;
0.1 to 15% by weight blocked catalysts;
0.1 to 2% by weight bonding agent;
0.1 to 4% by weight liquid type stress modifier;
0.1 to 2% by weight degassing agent; and
0.1 to 5% by weight functionalized graphene oxide as filler.

In another preferred embodiment, the solder flux comprises:
20 to 40% by weight organic high-boiling solvents;
5 to 45% by weight epoxy resins;
2 to 36% by weight hardeners;
10 to 20% by weight carboxylic acid as an activator;
0.1 to 15% by weight blocked catalysts;
0.1 to 2% by weight bonding agent;
0.1 to 4% by weight liquid type stress modifier; and
0.1 to 40% by weight silica as filler.

In another preferred embodiment, the solder flux comprises:
20 to 40% by weight organic high-boiling solvents;
5 to 45% by weight epoxy resins;
2 to 36% by weight hardeners;
10 to 20% by weight carboxylic acid as an activator;
0.1 to 15% by weight blocked catalysts;
0.1 to 2% by weight bonding agent;
0.1 to 4% by weight liquid type stress modifier;
0.1 to 2% by weight degassing agent; and
0.1 to 5% by weight graphite based as fillers.

In a further aspect, the present invention provides a solder paste comprising the solder flux described herein and solder particles.

In a further aspect, the present invention provides use of the solder flux described herein to strengthen a solder joint and/or interconnection.

In a further aspect, the present invention provides a use of the solder flux described herein to control the spread of flux residue formed around a solder joint during a solder joint manufacturing method.

In a further aspect, the present invention provides a use of the solder flux described herein to control the mechanical properties of a flux residue formed after reflow.

In a further aspect, the present invention provides use of a solder flux residue obtainable from the solder flux described herein to enhance the thermo-mechanical properties of a solder-pad interface or a solder joint to result in a more reliable solder-pad interlace or solder joint.

In a further aspect, the present invention provides a solder flux comprising:
an epoxy resin; and
a liquid rubber dispersed in the epoxy resin,

wherein the liquid rubber comprises an acrylonitrile butadiene type rubber having one or more terminal groups comprising carboxyl, hydroxyl and/or amine groups.

The preferable and optional features and the advantages of the first aspect of the present invention apply equally to this aspect of the present invention.

The solder flux preferably comprises from 1 to 10 wt. % of the liquid rubber based on the total weight of the solder flux.

In a further aspect, the present invention provides a method of forming a solder joint, the method comprising:
(i) providing two or more work pieces to be joined;
(ii) providing a solder paste comprising solder particles, a flux and a residue-forming material; and
(iii) heating the solder paste in the vicinity of the work pieces to be joined to form a solder joint,

wherein on heating the solder paste the residue-forming material forms a residue which completely covers the solder joint.

The residue-forming material may be separate to the flux. Alternatively, the residue-forming material may be the flux.

The residue-forming material and/or flux advantageously does not migrate far from the joint interface during the heating of the solder paste.

The residue completely covers the solder joint. This means that the residue completely covers the exposed outer surface of the solder joint, i.e. the exposed surfaces not directly in contact with the work pieces.

In an alternative aspect, the residue does not completely cover the solder joint but instead covers at least 50% of the exposed area of the solder joint, preferably at least 90% of the exposed area, more preferably at least 95% of the exposed area, even more preferably substantially all of the exposed area.

The two or more work pieces to be joined typically comprise an electronic component (such as, for example, a chip resistor or a chip capacitor) and a copper pad (typically disposed on a printed circuit board).

Residue-forming materials and/or fluxes suitable for use in the present invention include, for example, thermoplastic polymers (such as, for example, polyamide, polybutyienes, polyimide, acrylic and acrylate) and thermosetting cross-linkable resins (such as, for example, epoxy, polyester, styranated polyester and phenolic).

In a further aspect, the present invention provides a method of forming a solder joint, the method comprising:
(i) providing two or more work pieces to be joined;
(ii) providing a solder paste comprising solder particles, a flux and a residue-forming material; and
(iii) heating the solder paste in the vicinity of the work pieces to be joined to form a solder joint,

wherein on heating the solder paste the majority of the flux and/or residue-forming material does not migrate from the joint interface.

In a further aspect, the present invention provides a method of forming a solder joint, the method comprising:
(i) providing two or more work pieces to be joined;
(ii) providing a solder paste comprising solder particles and a flux; and
(iii) heating the solder paste in the vicinity of the work pieces to be joined to form a solder joint,

wherein on heating the solder paste the flux forms a residue which completely covers the solder joint.

In a further aspect, the present invention provides a method of forming a solder joint, the method comprising:
(i) providing two or more work pieces to be joined;
(ii) providing a solder paste comprising solder particles, a flux and a residue-forming material; and
(iii) heating the solder paste in the vicinity of the work pieces to be joined to form a solder joint,

wherein on heating the solder paste the residue-forming material forms a residue which coats the solder joint to increase the mechanical strength thereof.

In a further aspect, the present invention provides a solder paste comprising:
solder particles;
a flux; and
a residue-forming material.

The paste may be in film form. The paste may be printable and/or jettable.

In a further aspect, the present invention provides a solder paste flux comprising a residue-forming material.

In a further aspect, the present invention provides a solder joint completely coated with a solder paste residue.

In a further aspect, the present invention provides a method of increasing the mechanical strength of a solder joint, the method comprising providing the solder joint with a complete coating of a solder paste residue.

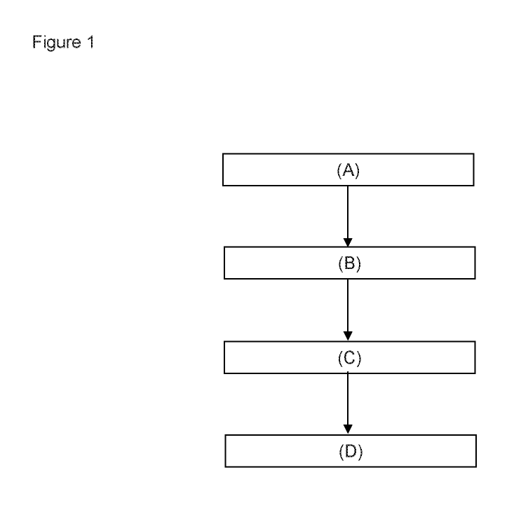

Referring to FIG. 1, there is shown a method of forming a solder joint, the method comprising: (A) providing a solder flux; (B) providing solder particles; (C) providing two or more work pieces to be joined; and (D) heating the solder flux and the solder particles in the vicinity of the two or more work pieces to be joined to form: (i) a solder joint between the two or more work pieces to be joined, and (ii) a solder flux residue, wherein the solder flux residue substantially covers the exposed surfaces of the solder joint.

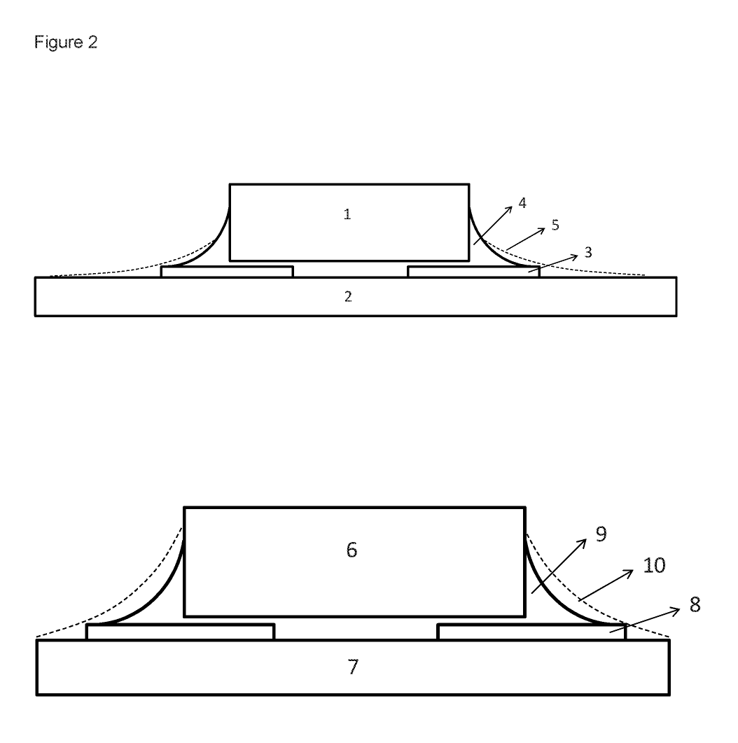

FIG. 2 (top) shows a schematic of a solder joint formed using a conventional method. During the manufacturing method, an electronic component 1, for example, a chip resistor, chip capacitors, etc., is placed on a given printed circuit board 2 by bonding the copper pads 3 of the said printed circuit board 2 by means of an interconnect material, namely the solder paste that forms the solder joint 4. The solder paste residue 5 spreads and does not completely cover the solder joint 4. As a consequence the spread residue 5 does not reinforce the solder joint 4.

FIG. 2 (bottom) shows a schematic of a solder joint formed using the method of the present invention. During the manufacturing method, an electronic component 6, for example, a chip resistor, chip capacitor, etc., is placed on a given printed circuit board 7 by bonding the copper pads 8 of the said printed circuit board 7 by means of an interconnect material, namely the solder paste that forms the solder joint 9. The spread of the solder paste is controlled and the solder paste residue 10 is retained at the site of the solder joint and surrounds the solder joint. As a result, the solder joint is reinforced.

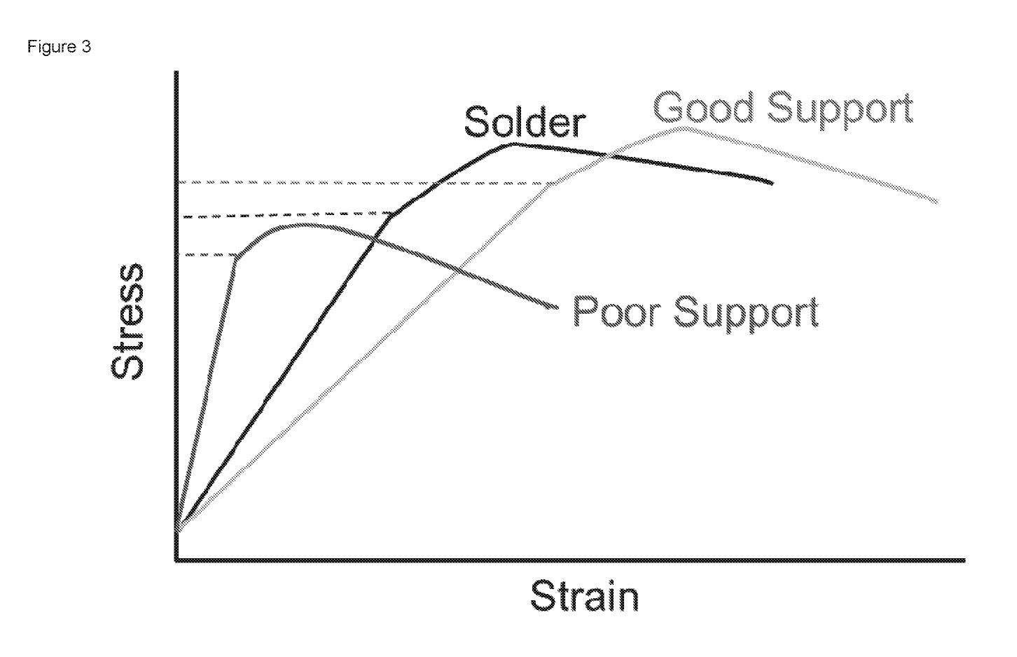

FIG. 3 shows hypothetical stress-strain curves of three materials. The curve in the middle is for the solder while two other materials are on either side of this. The curve on the left shows typical behavior of a brittle, high modulus and low strength material (e.g. conventional solder flux residue). Such a material breaks easily and shows small elongation at breaking point. If this type of material is used along with the solder, it is unlikely to improve the mechanical strength of the joint. On the other side, the curve shows a typical stress-strain plot of a ductile material (e.g. the solder flux residue formed by the solder flux of the present invention). This material has lower modulus than the solder and strength is higher. It has higher elastic deformation and elongation at breaking point is also higher. Such a material used along with solder will increase the strength of the joint with the resulting joint able to withstand much higher stress.

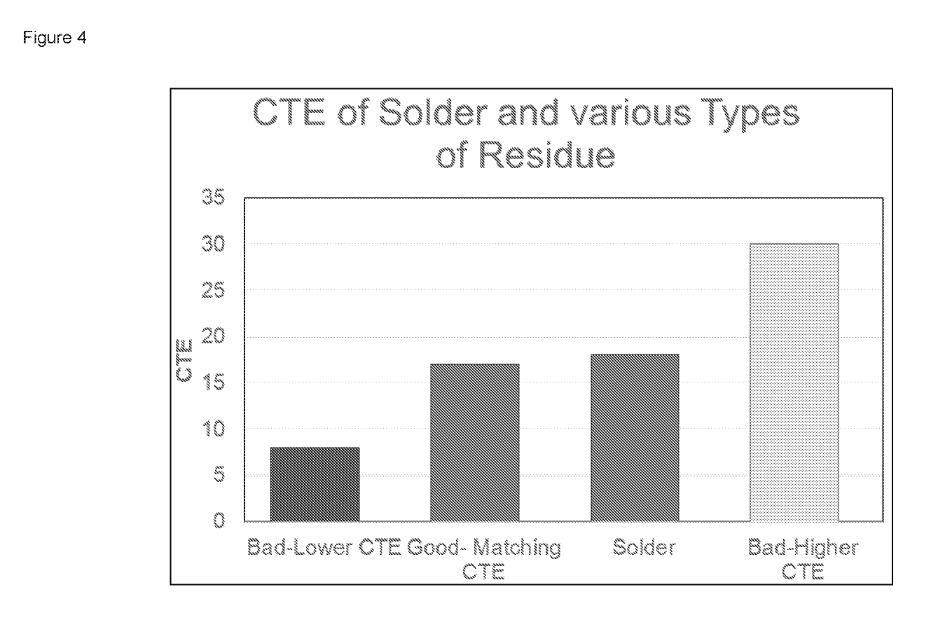

Thermo-mechanical fatigue is usually evaluated using thermal cycling testing. Presence or absence of flux residue on the solder joint affects the joint strength and the thermal cycling performance of the said joint. Presence of flux residue can act favorably or adversely on the solder joint's thermo-mechanical reliability, depending on its properties. FIG. 4 shows Coefficients of Thermal Expansion (CTE) of a typical solder and three types of other joint reinforcing materials that could be potentially used in electronic assembly. A typical Pb-free solder has CTE around 18-20 PPM/C. A good enforcing material should have a CTE as close to the solder as possible (e.g. a solder flux residue formed by the solder flux of the present invention). Material shown on the extreme left in the picture has much lower CTE than the solder. This material will expand and contract at much different rate than the solder. Therefore, such a material will increase stresses at the interfaces during temperature cycling test and result in a poor thermal fatigue life. Similarly, material shown on the extreme right has much higher CTE than the solder. If such a material is applied to reinforce a solder joint, it will also increase stresses at the interfaces during temperature cycling test.

The invention will now be described in relation to the following non-limiting example.

### Example 1

Different solders fluxes A-F were prepared having components falling within the following ranges:
from 20 to 40 wt. % organic solvent; and/or
from 5 to 45 wt. % epoxy resin; and/or
from 2 to 36 wt. % hardener; and/or
from 0.1 to 15 wt. % catalyst; and/or
from 10 to 20 wt. % activator; and/or
from 0.1 to 2 wt. % bonding agent; and/or
from 0.1 to 4 wt % stress modifier; and/or
from 0.1 to 2 wt. % degassing agent.

Solder fluxes A-F were used to form solder joints using the method of the present invention, and the resulting solder joints were subjected to testing.

Impact Bend Testing:

Impact reliability of portable electronic devices is a major concern, as they are often subjected to accidental mechanical shock, vibration, and bending in day to day use. Mechanical shock and vibration can induce high frequency PCB bending with an accompanied strain in the range of 1000με to 3000με. In fact, most of the solder interconnect failures during drop testing is due to flexural oscillation. A high speed board level cyclic bending method is chosen to assess the new material performance. In this method both strain (displacement) and strain rate (bending speed) can be controlled accurately. The test vehicle is subjected to cyclic bending with the help of a linear motor (magnetic piston) at a constant deflection with an accuracy of ±0.05 mm. All the test parameters such as resistance, deflection, bending speed and force were continuously monitored.

The machine operation is completely controlled through custom Labview software and it can automatically stop depending on the threshold resistance.

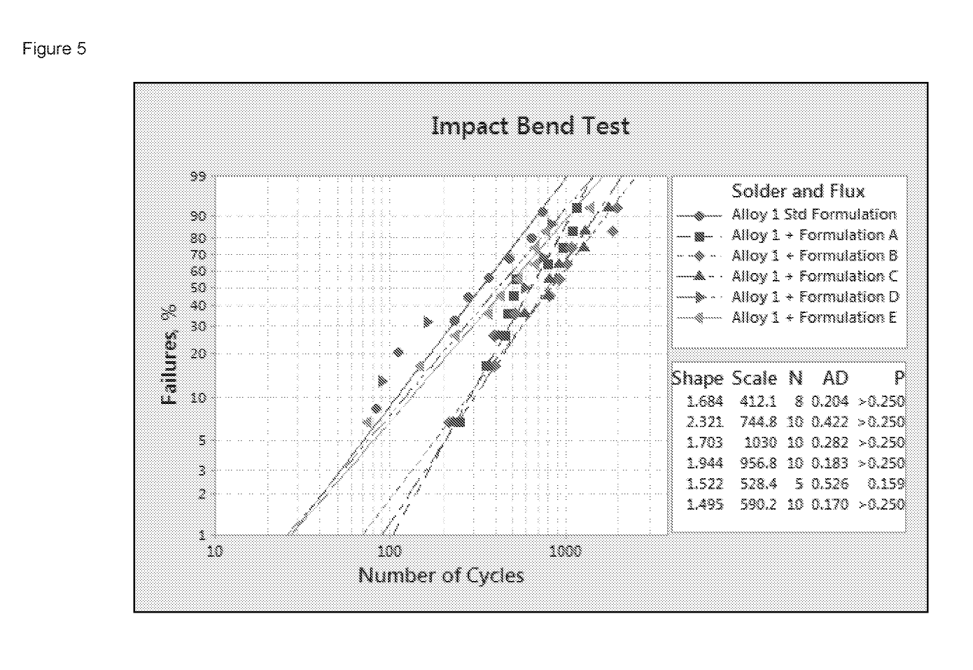

FIG. 5 shows Impact Bend Test results of a standard solder paste side by side with five new formulations made with the same alloy and solder fluxes A-E. The circles correspond to the standard solder paste, whereas formulations A-E are represented by square, diamonds, up pointing triangles, right pointing triangles and left pointing triangles, respectively. Standard paste has little or no effect of the flux residue on the mechanical strength of the joint. Standard paste shows characteristic life of 412 impact bend cycles while new formulations show characteristic life varying from 528 cycles to 1030 cycles. That means that by controlling the paste flux residue properties one can get 28% to 250% improvement in Impact Bend Test characteristic life.

Drop Shock Testing:

Drop shock testing was performed under a variation of the JESD22-B111 standard in which BGA components are replaced by RF shield cans.

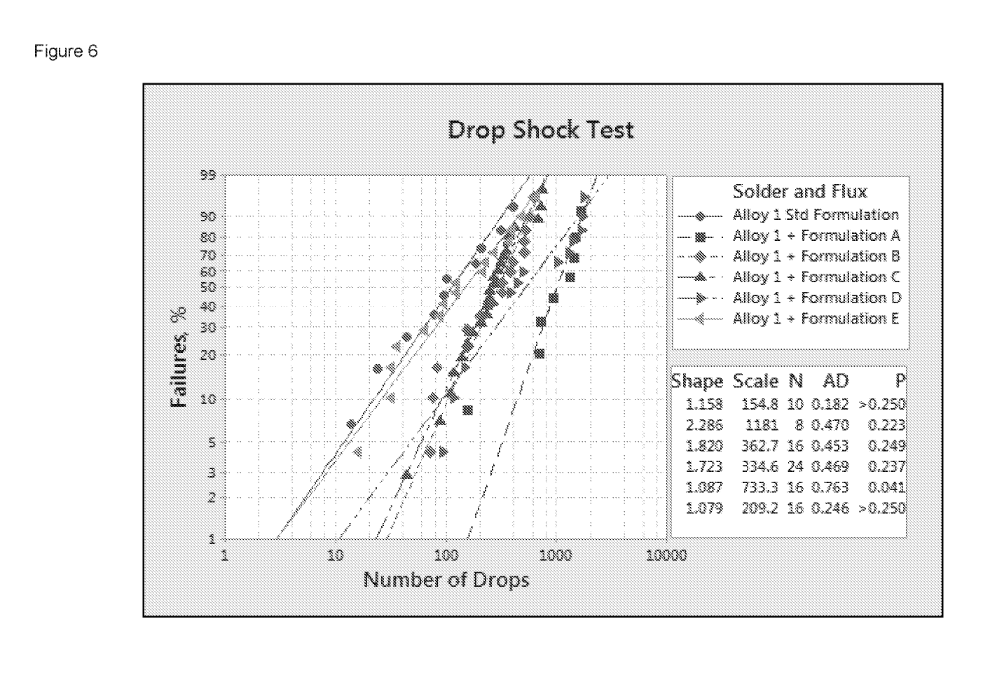

FIG. 6 shows Drop Shock Test results of a standard solder paste side by side with five new formulations made with the same alloy and solder fluxes A-E. The same key is applied as in the impact bend testing. Standard paste shows characteristic life of 155 drops while new formulations show characteristic life varying from 209 drops to 1181 drops. That means by controlling the paste flux residue properties one can get 35% to 662% improvement in Drop Shock characteristic life.

Table 1 shows a summary of the characteristic life in Impact Bend Test and Drop Shock Test of the pastes evaluated. Even though all the new paste formulations show an improvement over the standard paste in both the tests, the order of magnitude of improvement is not the same. A careful examination of the data shows that paste with highest characteristic life in Impact Bend Test does not necessarily mean high characteristic life in Drop Shock Test. For example Formulations B and C shows Impact Bend Test characteristic life of 1030 and 957 cycles respectively while the same pastes show 363 and 335 drops characteristic life in Drop Shock Test respectively. However, reverse might be true. That means a long characteristic life in Drop Shock Test may indicate a long characteristic life in Impact Bend Test as well. For example Formulation A showing the longest characteristic of 1181 drops in Impact Bend Test has shown Impact Bend Test characteristic life of 745 cycles. This shows that different formulations' residue has different mechanical properties especially strain rate dependence of the modulus/strength. Since the strain rate experienced in Drop Shock Test is higher than that in Impact Bend Test, a material with high strength at high strain rate will perform the best. At low strain rate, a brittle material with high modulus and lower elongation can also show good performance. But such a material will perform poorly in high strain rate tests. Therefore it is important to design a flux system whose residue, remaining at the solder joint after completion of soldering process, has the desired mechanical properties.

TABLE 1
Summary of Impact Bend Test results
and Drop Shock Test Results.

| | Impact Bend Test | Drop Shock Test |
|---|---|---|
| Solder and Flux | Characteristic Life | Characteristic Life |
| Alloy 1 Standard Formulation | 412 | 155 |
| Alloy 1 + Formulation A | 745 | 1181 |
| Alloy 1 + Formulation B | 1030 | 363 |
| Alloy 1 + Formulation C | 957 | 335 |
| Alloy 1 + Formulation D | 528 | 733 |
| Alloy 1 + Formulation E | 590 | 209 |

Thermal Cycling Testing:

Thermal cycling test was performed as per the IPC9701 standard, from −40° C. to +125° C., with 10 min dwell time on each side. A thermal shock chamber from Espec (model TSA-101S) capable of fast heating and cooling rates was used for the testing. The test vehicle is a printed circuit board with a Cu-OSP surface finish in which a pattern of 16 chip resistors #1206 is mounted. The test vehicles are placed in the thermal cycling chamber for the duration of the test. Every 500 thermal cycles five of these test vehicles were removed and the shear strength of the #1206 chip resistors is evaluated. Shear test of chip resistors was conducted on a Condor Sigma system, as per the JIS Z3198-7:2003 standard. The results presented here are the resulting average of a minimum of 48 individual shear strength measurements. These test vehicles were assembled with standard formulation paste made with a lead free alloy (alloy 2) and another paste designed to produce residue to provide additional strength to the interconnects.

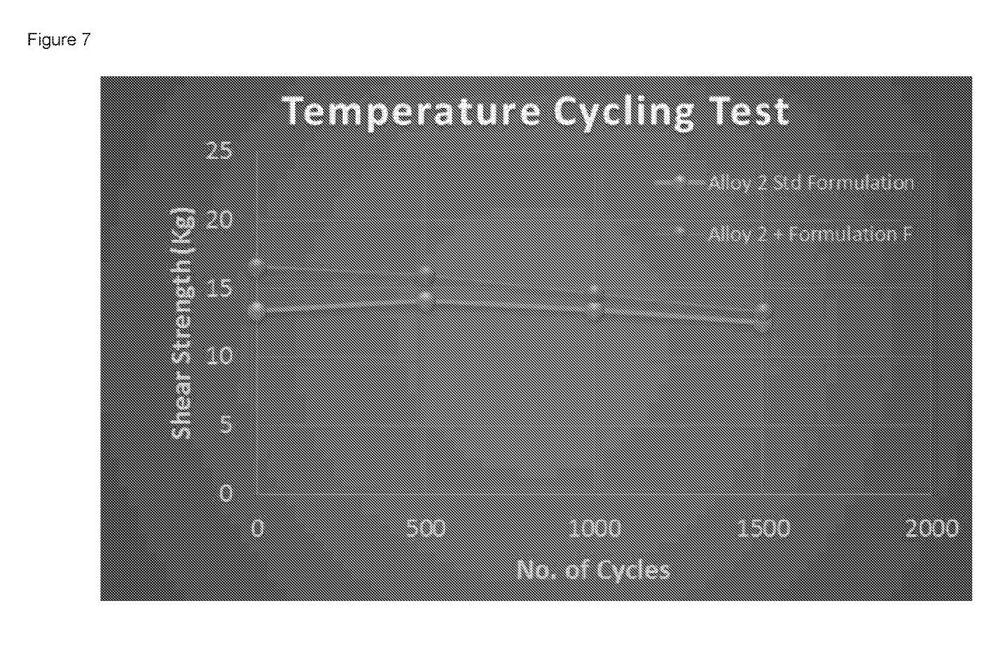

FIG. 7 shows results of the Temperature Cycling Test of the standard formulation and a formulation formed of solder flux F. Mechanical strength of interface as measured by the passive component, Chip Resistor 1206, is shown as a function of the number of temperature cycles. Initial shear strength of the joints formed with designed residue paste is about 25% higher than the standard paste. After 1500 cycles, its strength is still higher than the standard paste but only by about 6%. This drop is possibly due to CTE difference between the residue and the solder. This can be further improved by optimizing the material composition to reduce the CTE mismatch.

Testing of Basic Properties:

Table 2 shows basic material properties of the flux residues. Key to performance is controlling these properties. Fraction of residue remaining after reflow is important to cover the solder interconnect which is important to provide additional mechanical strength. Peak residue transition temperature is important to make sure that flux residue remaining on the solder joint is completely transformed into strong solid material capable of adding strength to the solder joint. Glass transition temperature is important to make sure that the materials do not degrade or change properties during high temperature operation or during temperature cycling or thermal shock tests.

TABLE 2
Basic material properties of the flux formulation material after reflow.

| | | Formulations | | | | | |
|---|---|---|---|---|---|---|---|
| Properties | Unit | A | B | C | D | E | F |
| Peak cure | ° C. | 167 | 156 | 115 | 153 | 164 | 158 |
| Temperature | | | | | | | |
| Tg by DSC or | ° C. | 114 | 121 | 123 | 136 | 112 | 74 |
| DMA or TMA | | | | | | | |
| Residue at | % | 34 | 36 | 35 | 38 | 37 | 24 |
| 250° C. (By | | | | | | | |
| TGA) | | | | | | | |

The foregoing detailed description has been provided by way of explanation and illustration, and is not intended to limit the scope of the appended claims. Many variations in the presently preferred embodiments illustrated herein will be apparent to one of ordinary skill in the art and remain within the scope of the appended claims and their equivalents.

1. A method of forming a solder joint, the method comprising:
providing a solder flux;
providing solder particles;
providing two or more work pieces to be joined; and
heating the solder flux and the solder particles in the vicinity of the two or more work pieces to be joined to form: (i) a solder joint between the two or more work pieces to be joined, and (ii) a solder flux residue,
wherein the solder flux residue substantially covers the exposed surfaces of the solder joint.

2. The method of claim 1, wherein the solder flux comprises:
an organic solvent;
an epoxy resin;
a hardener; and
a catalyst.

3. The method of claim 2, wherein the solder flux further comprises:
an activator; and/or
a bonding agent; and/or
a stress modifier; and/or
a degassing agent.

4. The method of claim 1, wherein the solder flux comprises, based on the total weight of the solder flux:
from 20 to 40 wt. % organic solvent; and/or
from 5 to 45 wt. % epoxy resin; and/or
from 2 to 36 wt. % hardener; and/or
from 0.1 to 15 wt. % catalyst; and/or
from 10 to 20 wt. % activator; and/or
from 0.1 to 2 wt. % bonding agent; and/or
from 0.1 to 4 wt. % stress modifier; and/or
from 0.1 to 2 wt. % degassing agent.

5. The method of claim 2, wherein the solder flux further comprises a filler.

6. The method of claim 5, wherein the solder flux comprises from 0.1 to 40 wt. % filler, based on the total weight of the solder flux.

7. The method of claim 5, wherein the filler comprises a high aspect ratio filler, the high aspect ratio filler comprising one or more of glass fibers, mica, nanoclays, graphene, functionalized graphene, diamond, carbon nano tubes, graphite and carbon fibers, boron nitride, synthetic and natural fibers.

8. The method of claim 5, wherein the filler comprises a low aspect ratio filler, the low aspect ratio filler comprising one or more of: silica, aluminum oxide, zinc oxide, aluminum nitride, dioxide, polyhedral oligomeric silsesquioxanes, metal-coated particles, talc, kaolin, wallastonite and glass spheres.

9. The method of claim 5, wherein the filler comprises an antiblock, lubricating filler comprising one or more of silica, calcium carbonate, PTFE and graphite-related fillers.

10. The method of claim 2, wherein the epoxy resin comprises a rubber dispersed therein.

11. The method of claim 10, wherein the epoxy resin comprises from 0.1 to 10 wt. % rubber based on the total weight of the solder flux.

12. The method of claim 10, wherein the rubber comprises an acrylonitrile butadiene type rubber having one or more terminal groups comprising carboxyl, hydroxyl and/or amine groups.

13. The method of claim 2, wherein the solder particles are lead-free solder particles.

14. The method of claim 1, wherein the two or more work pieces to be joined comprise an electronic component and a copper pad of a printed circuit board.

15. The method of claim 1, wherein the solder joint is formed during a manufacturing method selected from: a surface mount technology (SMT) method, a die and component attach method, a package on package (POP) method, a chip scale package (CSP) method, a ball grid array (BGA) method, a flip chip method, a can shield attachment method and a camera lens attachment method.

16. A solder joint obtainable by the method of claim 1.

17. A solder flux comprising:
an organic solvent;
an epoxy resin;
a hardener; and
a catalyst,
and optionally one or more of:
an activator;
a bonding agent;
a stress modifier;
a degassing agent; and
a filler.

18. The solder flux of claim 17, wherein the epoxy resin comprises a rubber dispersed therein.

19. The solder flux of claim 18, wherein the epoxy resin comprises from 0.1 to 10 wt. % rubber based on the total weight of the solder flux.

20. The solder flux of claim 18, wherein the liquid rubber comprises an acrylonitrile butadiene type rubber having one or more terminal groups comprising carboxyl, hydroxyl and amine groups.

21. The solder flux of claim 17, wherein the solder flux is printable, and/or jettable, and/or dippable and/or pin-transferable.

22. The solder flux of claim 17, further comprising solder particles, wherein the solder flux is in the form of a solder paste.

23. (canceled)

24. (canceled)

25. (canceled)

26. (canceled)

27. A solder flux comprising:
an epoxy resin; and
a liquid rubber dispersed in the epoxy resin,
wherein the liquid rubber comprises an acrylonitrile butadiene type rubber having one or more terminal groups comprising carboxyl, hydroxyl and/or amine groups.

28. The solder flux of claim 27, wherein the solder flux comprises from 1 to 10 wt. % of the liquid rubber based on the total weight of the solder flux.

29. The method of claim 5, wherein the filler comprises at least one of:
a) a high aspect ratio filler, the high aspect ratio filler comprising one or more of glass fibers, mica, nanoclays, graphene, functionalized graphene, diamond, carbon nano tubes, graphite and carbon fibers, boron nitride, synthetic and natural fibers;
b) a low aspect ratio filler, the low aspect ratio filler comprising one or more of: silica, aluminum oxide, zinc oxide, aluminum nitride, dioxide, polyhedral oligomeric silsesquioxanes, metal-coated particles, talc, kaolin, wallastonite and glass spheres; and
c) an antiblock, lubricating filler comprising one or more of silica, calcium carbonate, PTFE and graphite-related fillers.
